(19) United States
(12) Patent Application Publication
(10) Pub. No.: US 2025/0393263 A1
(43) Pub. Date: Dec. 25, 2025

(54) SEMICONDUCTOR DEVICE

(71) Applicant: DB HiTek Co., Ltd., Seoul (KR)

(72) Inventors: Seung Hyun KIM, Bucheon-si (KR); Hee Bae LEE, Bucheon-si (KR); Soon Jong PARK, Bucheon-si (KR); Sung Kyung JUNG, Bucheon-si (KR)

(73) Assignee: DB HiTek Co., Ltd., Seoul (KR)

(21) Appl. No.: 18/799,866

(22) Filed: Aug. 9, 2024

(30) Foreign Application Priority Data
Jun. 25, 2024 (KR) 10-2024-0082676

(51) Int. Cl. H01L 29/06

(52) U.S. Cl. CPC H10D 62/107

(57) ABSTRACT

A semiconductor device comprising, a substrate, a first active region on the substrate, a second active region on the substrate separated from the first active region, a common termination region between the first active region and the second active region, a junction termination extension (JTE) region surrounding the first active region and the second active region, a first termination region between the JTE region and the first active region, surrounding the first active region; and a second termination region between the JTE region and the second active region, surrounding the second active region, wherein a portion of the first termination region and a portion of the second termination region are connected to each other at the common termination region.

### CROSS-REFERENCE TO RELATED APPLICATION

This application claims priority under 35 U.S.C § 119 to Korean Patent Application No. 10-2024-0082676 filed on Jun. 25, 2024, in the Korean Intellectual Property Office, the entire contents of which are hereby incorporated by reference.

### TECHNICAL FIELD

The present invention relates to semiconductor devices, and particularly, to semiconductor devices having a common termination region.

### BACKGROUND

The statements in this section merely provide background information related to the present embodiment and do not necessarily constitute the prior art.

A bi-directional power switch is a switch device that allows bidirectional current control by connecting two power devices (MOSFETs or JFETs) to a common drain or common source. A bi-directional power switch allows charging and discharging to occur simultaneously. In a normal bidirectional conduction state, a bidirectional power switch can play the role of blocking current in an unnecessary direction. Accordingly, in a bidirectional power switch, the two power devices must be able to operate individually as separate devices, and low conduction loss is required to achieve high efficiency. Therefore, the distance between the two power devices must be short.

Meanwhile, to achieve the specifications required for a bidirectional power switch, each of the two power devices may include a termination region having a ring structure. However, the terminal region of this ring structure may occupy a significant portion of the area, so an optimized structure is required. Furthermore, because both power devices require separate termination regions, there is a need for a device structure to achieve high efficiency while including respective termination regions.

### SUMMARY

An object of the present invention is to provide a semiconductor device that can reduce a chip size by allowing two power devices to have a common termination region.

Additionally, an object of the present invention is to provide a semiconductor device that can reduce the distance between two power devices by allowing the termination regions of the two power devices to be connected at a common termination region.

The objects of the present invention are not limited to the objects mentioned above, and other objects and advantages of the present invention that are not mentioned can be understood by the following description and will be more clearly understood from the embodiments of the present invention. Additionally, it will be readily apparent that the objects and advantages of the present invention can be realized by the means and combinations thereof indicated in the patent claims.

According to some aspects of the disclosure, a semiconductor device comprises, a substrate, a first active region on the substrate, a second active region on the substrate separated from the first active region, a common termination region between the first active region and the second active region, a junction termination extension (JTE) region surrounding the first active region and the second active region, a first termination region between the JTE region and the first active region, surrounding the first active region, and a second termination region between the JTE region and the second active region, surrounding the second active region, wherein a portion of the first termination region and a portion of the second termination region are connected to each other at the common termination region.

According to some aspects, the first termination region includes one or more first doping rings and a first outer doping ring surrounding the one or more first doping rings, and the second termination region includes one or more second doping rings and a second outer doping ring surrounding the one or more second doping rings.

According to some aspects, a first portion of the JTE region disposed between the first outer doping ring and the second outer doping ring in the common termination region, wherein a portion of the first termination region and a portion of the second termination region are connected to each other by the first outer doping ring, the second outer doping ring, and the first portion of the JTE region in the common termination region.

According to some aspects, the one or more first doping rings include a first sub-ring and a second sub-ring that are spaced apart from each other, a second portion of the JTE region is disposed between the first sub-ring and the second sub-ring, and the one or more first doping rings and the first outer doping ring are connected to each other by a third portion of the JTE region.

According to some aspects, a common doping region, to which the first outer doping ring and the second outer doping ring are connected, in the common termination region, wherein a portion of the first termination region and a portion of the second termination region are connected to each other by the common doping region in the common termination region.

According to some aspects, the one or more first doping rings include a first sub-ring and a second sub-ring that are spaced apart from each other, a second portion of the JTE region is disposed between the first sub-ring and the second sub-ring, and the one or more first doping rings and the common doping region are connected to each other by a third portion of the JTE region.

According to some aspects, a width of the common doping region is equal to widths of the one or more first doping rings.

According to some aspects, a width of the common doping region is greater than widths of the one or more first doping rings.

According to some aspects of the disclosure, a semiconductor device comprises, a substrate, a first active region on the substrate, a second active region on the substrate separated from the first active region, a common termination region between the first active region and the second active region, a junction termination extension (JTE) region disposed within the substrate, being a partial region of the substrate including an upper surface of the substrate in the common termination region, a first well and a second well disposed within the JTE region of the common termination region and spaced apart from each other, a first outer doping ring surrounding the first active region and disposed between the first well and the second well within the JTE region of the common termination region, one or more first doping rings surrounding the first active region and disposed between the first well and the first outer doping ring within the JTE region of the common termination region, and one or more second doping rings surrounding the second active region and disposed between the second well and the first outer doping ring within the JTE region of the common termination region.

According to some aspects, a second outer doping ring surrounding the second active region and disposed between the first outer doping ring and the one or more second doping rings within the JTE region of the common termination region, wherein the first outer doping ring and the second outer doping ring are connected to each other by a first portion of the JTE region.

According to some aspects, the one or more first doping rings include a first sub-ring and a second sub-ring that are spaced apart from each other, a second portion of the JTE region is disposed between the first sub-ring and the second sub-ring, and the one or more first doping rings and the first outer doping ring are connected to each other by a third portion of the JTE region.

According to some aspects, a second outer doping ring surrounding the second active region and the one or more second doping rings; and a common doping region, to which the first outer doping ring and the second outer doping ring are connected, within the JTE region of the common termination region.

According to some aspects, the one or more first doping rings include a first sub-ring and a second sub-ring that are spaced apart from each other, a second portion of the JTE region is disposed between the first sub-ring and the second sub-ring, and the one or more first doping rings and the common doping region are connected to each other by a third portion of the JTE region.

According to some aspects, a width of the common doping region is equal to widths of the one or more first doping rings.

According to some aspects, a width of the common doping region is greater than widths of the one or more first doping rings.

According to some aspects of the disclosure, a semiconductor device comprises, a substrate, a first active region on the substrate, a second active region on the substrate separated from the first active region, a common termination region between the first active region and the second active region, a junction termination extension (JTE) region disposed within the substrate, being a partial region of the substrate including an upper surface of the substrate in the common termination region, a first well and a second well disposed within the JTE region of the common termination region and spaced apart from each other, a common doping region disposed between the first well and the second well within the JTE region of the common termination region, one or more first doping rings surrounding the first active region and disposed between the first well and the common doping region within the JTE region of the common termination region, and one or more second doping rings surrounding the second active region and disposed between the second well and the common doping region within the JTE region of the common termination region.

According to some aspects, the common doping region and the one or more first doping regions are connected to each other by a first portion of the JTE region, and the common doping region and the one or more second doping regions are connected to each other by a second portion of the JTE region.

According to some aspects, the one or more first doping rings include a first sub-ring and a second sub-ring, the first sub-ring and the second sub-ring are connected to each other by a third portion of the JTE region, the one or more second doping rings include a third sub-ring and a fourth sub-ring, and the third sub-ring and the fourth sub-ring are connected to each other by a second portion of the JTE region.

According to some aspects, the one or more first doping rings include a first sub-ring, the one or more second doping rings include a second sub-ring, and a width of the common doping region, a width of the first sub-ring, and a width of the second sub-ring are the same.

According to some aspects, the one or more first doping rings include a first sub-ring, the one or more second doping rings include a second sub-ring, and a width of the common doping region is wider than a width of the first sub-ring and a width of the second sub-ring.

Aspects of the disclosure are not limited to those mentioned above and other objects and advantages of the disclosure that have not been mentioned can be understood by the following description and will be more clearly understood according to embodiments of the disclosure. In addition, it will be readily understood that the objects and advantages of the disclosure can be realized by the means and combinations thereof set forth in the claims.

The semiconductor device of the present invention can reduce a chip size by allowing two power devices to have a common termination region.

Additionally, the semiconductor device of the present invention can have low conduction loss by reducing the distance between two power devices by allowing the termination regions of the two power devices to be connected at a common termination region.

In addition to the above-described content, specific advantages of the present invention are described below while explaining specific details for carrying out the invention.

### BRIEF DESCRIPTION OF THE DRAWINGS

FIG. 1 is a plan view of a semiconductor device according to an embodiment of the present invention.

FIG. 2 is an enlarged view of region M in FIG. 1.

FIG. 3 is a cross-sectional view taken along line A-A in FIG. 2.

FIG. 4 is an enlarged view of region N in FIG. 1.

FIG. 5 is a cross-sectional view taken along line A-A in FIGS. 2 and 4.

FIG. 6 is an enlarged view of region N in FIG. 1.

FIG. 7 is a cross-sectional view taken along line A-A in FIGS. 2 and 4.

FIG. 8 is an enlarged view of region N in FIG. 1.

FIG. 9 is a cross-sectional view taken along line A-A in FIGS. 2 and 4.

FIG. 10 is a cross-sectional view of a conventional semiconductor device.

### DETAILED DESCRIPTION OF THE PREFERRED EMBODIMENTS

The terms or words used in the disclosure and the claims should not be construed as limited to their ordinary or lexical meanings. They should be construed as the meaning and concept in line with the technical idea of the disclosure based on the principle that the inventor can define the concept of terms or words in order to describe his/her own inventive concept in the best possible way. Further, since the embodiment described herein and the configurations illustrated in the drawings are merely one embodiment in which the disclosure is realized and do not represent all the technical ideas of the disclosure, it should be understood that there may be various equivalents, variations, and applicable examples that can replace them at the time of filing this application.

Although terms such as first, second, A, B, etc. used in the description and the claims may be used to describe various components, the components should not be limited by these terms. These terms are only used to differentiate one component from another. For example, a first component may be referred to as a second component, and similarly, a second component may be referred to as a first component, without departing from the scope of the disclosure. The term ‘and/or’ includes a combination of a plurality of related listed items or any item of the plurality of related listed items.

The terms used in the description and the claims are merely used to describe particular embodiments and are not intended to limit the disclosure. Singular forms are intended to include plural forms unless the context clearly indicates otherwise. In the application, terms such as “comprise,” “comprise,” “have,” etc. should be understood as not precluding the possibility of existence or addition of features, numbers, steps, operations, components, parts, or combinations thereof described herein.

Unless otherwise defined, the phrases “A, B, or C,” “at least one of A, B, or C,” or “at least one of A, B, and C” may refer to only A, only B, only C, both A and B, both A and C, both B and C, all of A, B, and C, or any combination thereof.

Unless being defined otherwise, all terms used herein, including technical or scientific terms, have the same meaning as commonly understood by those skilled in the art to which the disclosure pertains.

Terms such as those defined in commonly used dictionaries should be construed as having a meaning consistent with the meaning in the context of the relevant art, and are not to be construed in an ideal or excessively formal sense unless explicitly defined in the application. In addition, each configuration, procedure, process, method, or the like included in each embodiment of the disclosure may be shared to the extent that they are not technically contradictory to each other.

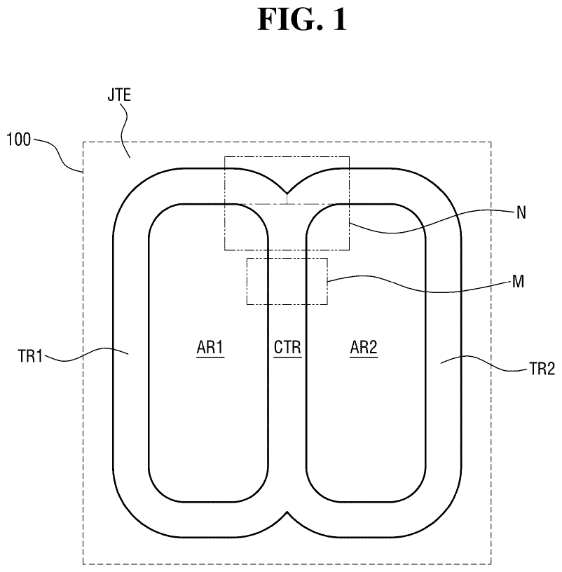

Hereinafter, a semiconductor device according to an embodiment of the present invention will be described with reference to FIGS. 1, 2, and 3.

FIG. 1 is a plan view of a semiconductor device according to an embodiment of the present invention. For clarity of the illustrations, the illustrations of some parts are omitted.

Referring to FIG. 1, a semiconductor device according to an embodiment of the present invention may include a substrate 100 including a first active region AR1, a second active region AR2, a first termination region TR1, a second termination region TR2, a JTE (Junction Termination Extension) region (JTE), and a common termination region CTR.

The first active region AR1 and the second active region AR2 may be separate regions on the substrate 100. The first active region AR1 and the second active region AR2 may be separated from each other by the common termination region CTR between the first active region AR1 and the second active region AR2.

The JTE region JTE may surround the first active region AR1 and the second active region AR2. The JTE region JTE may be doped with a first type of impurities. The JTE region JTE may be doped in a first concentration.

The first termination region TR1 may be disposed between the JTE region JTE and the first active region AR1. The first termination region TR1 surrounds the first active region AR1, and a portion of the first termination region TR1 may be disposed in the common termination region CTR.

The second termination region TR2 may be disposed between the JTE region JTE and the second active region AR2. The second termination region TR2 surrounds the second active region AR2, and a portion of the second termination region TR2 may be disposed in the common termination region CTR.

The common termination region CTR may be a region between the first active region AR1 and the second active region AR2. In the common termination region CTR, the first termination region TR1 and the second termination region TR2 may be connected to each other.

In some embodiments, the first termination region TR1 and the second termination region TR2 in the common termination region CTR may be connected to each other by a portion of the JTE region JTE.

In some embodiments, the first termination region TR1 and the second termination region TR2 in the common termination region CTR may be connected to each other by a common doping region.

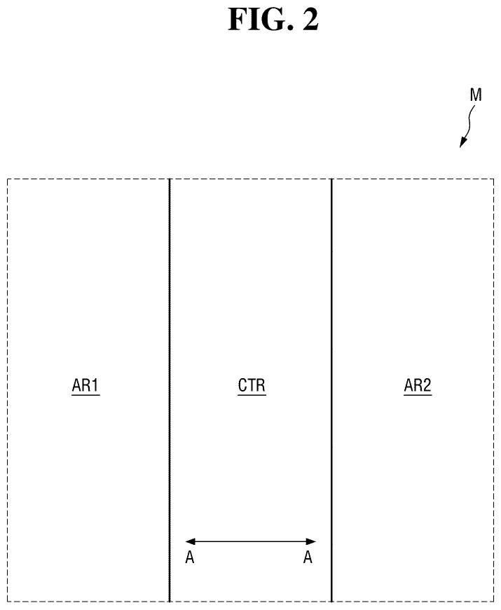

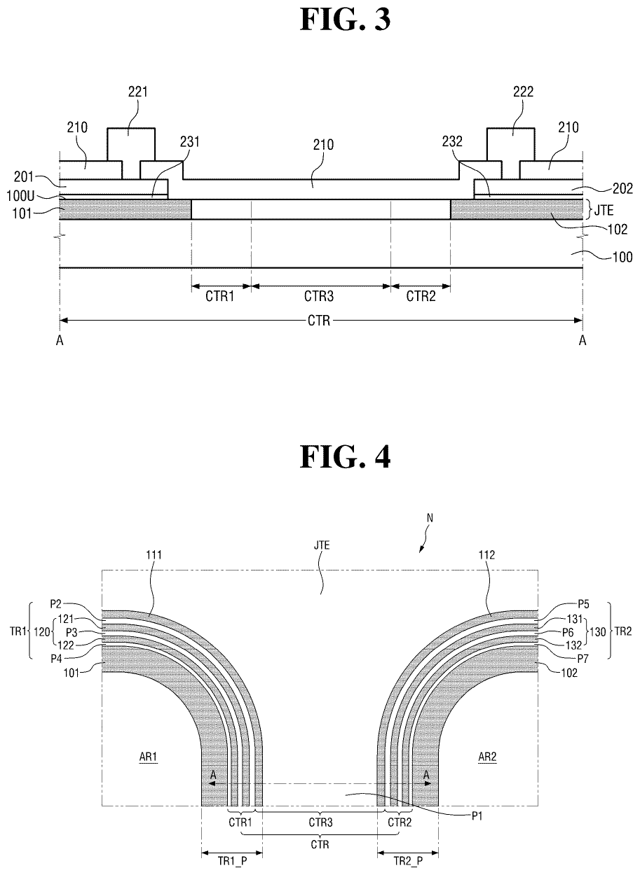

FIG. 2 is an enlarged view of region M in FIG. 1. FIG. 3 is a cross-sectional view taken along line A-A in FIG. 2.

Referring to FIGS. 1, 2, and 3, a semiconductor device according to an embodiment of the present invention includes a first well 101, a second well 102, a first gate electrode 201, a second gate electrode 202, an insulating layer 210, a first gate contact 221, and a second gate contact 222.

The JTE region JTE of the common termination region CTR may be a partial region of the substrate 100 including an upper surface 100U of the substrate 100. The JTE region JTE of the common termination region CTR may include the first well 101 and the second well 102 that are spaced apart from each other. The first well 101 and the second well 102 may be regions doped with a first type of impurities. The first well 101 and the second well 102 may be doped in a second concentration. The second concentration may be a higher concentration than the first concentration of the JTE region JTE.

The common termination region CTR may include a first common termination region CTR1, a second common termination region CTR2, and a third common termination region CTR3. The first common termination region CTR1, the second common termination region CTR2, and the third common termination region CTR3 may be located between the first well 101 and the second well 102. The first common termination region CTR1, the second common termination region CTR2, and the third common termination region CTR3 may be included in the JTE region JTE. The third common termination region CTR3 may be located between the first common termination region CTR1 and the second common termination region CTR2.

The first common termination region CTR1 may include a portion of the first termination region TR1. For example, the first common termination region CTR1 may include one or more first doping rings. The one or more first doping rings may surround the first active region AR1, and a portion of the one or more first doping rings may be disposed in the first common termination region CTR1 of the common termination region CTR.

The one or more first doping rings may be doped with a first type of impurities. The one or more first doping rings may be doped in a third concentration. The third concentration may be a higher concentration than the first concentration. The third concentration may be equal to or higher than the second concentration.

The one or more first doping rings in the first common termination region CTR1 may include various numbers of doping rings. For example, when there is a plurality of doping rings, the plurality of first doping rings may be spaced apart from each other. Portions of the JTE region JTE may be disposed between the plurality of first doping rings that are spaced apart from each other. The plurality of first doping rings spaced apart from each other may be connected to each other by portions of the JTE region JTE. For example, the first-first doping ring (for example, first sub-ring) and the second-first doping ring (for example, second sub-ring) may be spaced apart from each other, and a portion of the JTE region JTE may be disposed between them. The first-first doping ring and the second-first doping ring may be connected to each other by a portion of the JTE region JTE.

When one or more first doping rings in the first common termination region CTR1 include a plurality of doping rings, the widths of the plurality of first doping rings may be the same or different from each other.

The second common termination region CTR2 may include a portion of the second termination region TR2. For example, the second common termination region CTR2 may include one or more second doping rings. The one or more second doping rings may surround the second active region AR2, and a portion of the one or more second doping rings may be disposed in the second common termination region CTR2 of the common termination region CTR.

The one or more second doping rings may be doped with a first type of impurities. The one or more second doping rings may be doped in a third concentration.

The one or more second doping rings in the second common termination region CTR2 may include various numbers of doping rings. For example, when there is a plurality of doping rings, the plurality of second doping rings may be spaced apart from each other. Portions of the JTE region JTE may be disposed between the plurality of second doping rings that are spaced apart from each other. The plurality of second doping rings spaced apart from each other may be connected to each other by portions of the JTE region JTE. For example, the first-second doping ring (for example, third sub-ring) and the second-second doping ring (for example, fourth sub-ring) may be spaced apart from each other, and a portion of the JTE region JTE may be disposed between them. The first-second doping ring and the second-second doping ring may be connected to each other due to a portion of the JTE region JTE.

When one or more second doping rings in the second common termination region CTR2 include a plurality of doping rings, the widths of the plurality of second doping rings may be the same or different from each other.

The third common termination region CTR3 may include a portion of the first termination region TR1 and a portion of the second termination region TR2. For example, the third common termination region CTR3 may include a first outer doping ring and a second outer doping ring. The first outer doping ring surrounds the first active region AR1, and a portion of the first outer doping ring may be disposed in the third common termination region CTR3 of the common termination region CTR. The second outer doping ring surrounds the second active region AR2, and a portion of the second outer doping ring may be disposed in the third common termination region CTR3 of the common termination region CTR.

The first outer doping ring and the second outer doping ring may be doped with a first type of impurities. The first outer doping ring and the second outer doping ring may be doped in a third concentration.

The first outer doping ring and the second outer doping ring may be connected to the common doping region in the third common termination region CTR3, or may be disposed to be spaced apart from each other.

When the first outer doping ring and the second outer doping ring are disposed to be spaced apart from each other in the third common termination region CTR3, a portion of the JTE region JTE may be disposed between the first outer doping ring and the second outer doping ring. Since a portion of the JTE region JTE is disposed between the first outer doping ring and the second outer doping ring in the third common termination region CTR3, the first outer doping ring and the second outer doping ring can be connected to each other by a portion of the JTE region JTE. That is, a portion of the first termination region TR1 and a portion of the second termination region TR2 in the third common termination region CTR3 can be connected to each other by a portion of the JTE region JTE in the common termination region CTR.

When the first outer doping ring and the second outer doping ring in the third common termination region CTR3 are connected in the common doping region, a portion of the JTE region JTE can be disposed between the common doping region and one or more first doping rings, and another portion of the JTE region JTE can be disposed between the common doping region and the one or more second doping rings. When the first outer doping ring and the second outer doping ring are connected in the third common termination region CTR3, a portion of the first termination region TR1 and a portion of the second termination region TR2 can be connected to each other in the common termination region CTR.

The first outer doping ring surrounds the first active region AR1 at the outermost edge among the plurality of rings in the first termination region TR1, and a portion of the first outer doping ring may be disposed in the third common termination region CTR of the common termination region CTR3. The first outer doping ring may be disposed between the first well 101 and the second well 102 within the JTE region JTE of the common termination region CTR.

The second outer doping ring surrounds the second active region AR2 at the outermost edge among the plurality of rings in the second termination region TR2, and a portion of the second outer doping ring may be disposed in the third common termination region CTR3 of the common termination region CTR. The second outer doping ring may be disposed between the first well 101 and the second well 102 within the JTE region JTE of the common termination region CTR.

The one or more first doping rings surround the first active region AR1 between the first active region AR1 and the first outer doping ring, and a portion of the one or more first doping rings may be disposed in the third common termination region CTR3 of the common termination region CTR. The one or more first doping rings may be disposed between the first well 101 and the first outer doping ring within the JTE region JTE of the common termination region CTR.

The one or more second doping rings surround the second active region AR2 between the second active region AR2 and the second outer doping ring, and a portion of the one or more second doping rings may be disposed in the third common termination region CTR3 of the common termination region CTR. The one or more second doping rings may be disposed between the second well 102 and the first outer doping ring and the second outer doping ring within the JTE region JTE of the common termination region CTR.

The first gate electrode 201 may be a gate electrode of the common termination region CTR. The first gate electrode 201 may be different from the gate electrode of the first active region AR1. The first gate electrode 201 may be disposed on the first gate insulating film 231. The first gate insulating film 231 may be disposed between the first gate electrode 201 and the JTE region JTE of the common termination region CTR.

The second gate electrode 202 may be a gate electrode of the common termination region CTR. The second gate electrode 202 may be different from the gate electrode of the second active region AR2. The second gate electrode 202 may be disposed on the second gate insulating film 232. The second gate insulating film 232 may be disposed between the second gate electrode 202 and the JTE region JTE of the common termination region CTR.

The insulating layer 210 may be disposed on the upper surface 100U of the substrate 100. The insulating layer 210 may be disposed to cover the first gate electrode 201, the first well 101, the first common termination region CTR1, the second common termination region CTR2, the third common termination region CTR3, the first well 101, and the second gate electrode 202. The insulating layer 210 may expose a portion of the first gate electrode 201 and a portion of the second gate electrode 202. The insulating layer 210 may contain an insulating material.

The first gate contact 221 may be disposed on the first gate electrode 201 exposed by the insulating layer 210. The first gate contact 221 may be electrically connected to the first gate electrode 201.

The second gate contact 222 may be disposed on the second gate electrode 202 exposed by the insulating layer 210. The second gate contact 222 may be electrically connected to the second gate electrode 202.

Each of the first common termination region CTR1, the second common termination region CTR2, and the third common termination region CTR3 may include one or more first doping rings of various numbers and/or widths, the first outer doping ring, the second outer doping ring, and one or more second doping rings.

Hereinafter, three examples in which each of the first common termination region CTR1, the second common termination region CTR2, and the third common termination region CTR3 includes one or more first doping rings of various numbers and/or widths, the first outer doping ring, the second outer doping ring, and one or more second doping rings will be described as examples.

Hereinafter, a semiconductor device according to some embodiments of the present invention will be described with reference to FIGS. 1, 2, 4, and 5. For clarity of explanation, the description of those overlapping with those explained previously will be simplified or omitted.

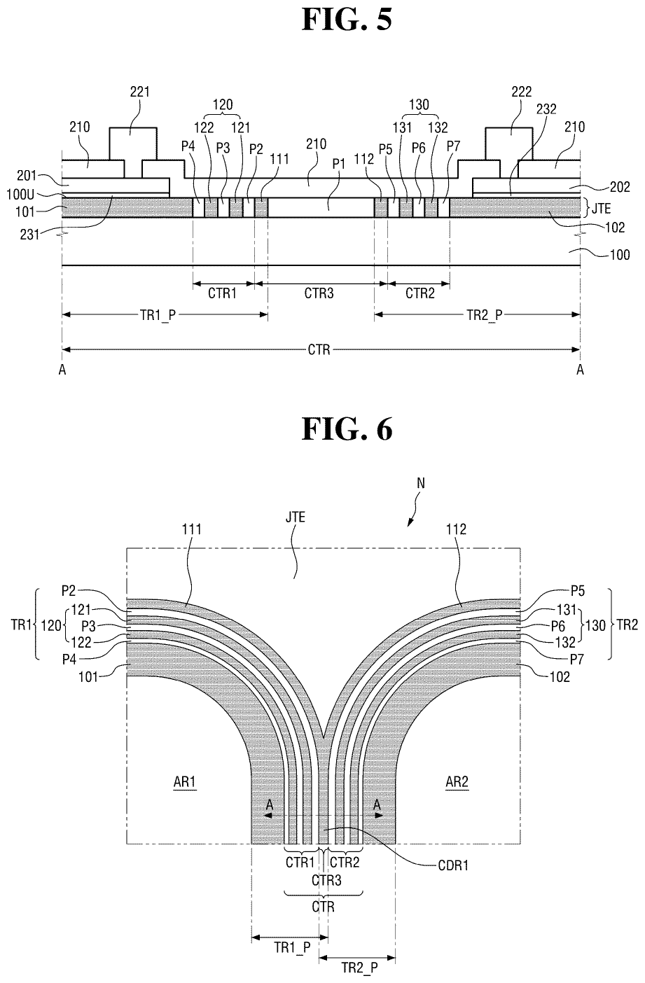

FIG. 4 is an enlarged view of region N in FIG. 1. FIG. 5 is a cross-sectional view taken along line A-A in FIGS. 2 and 4.

Referring to FIGS. 1, 2, 4, and 5, a semiconductor device according to some embodiments of the present invention may include a first outer doping ring 111, a first portion P1 of the JTE region JTE, and a second outer doping ring (112) in the third common termination region CTR3.

The first common termination region CTR1 may include a portion TR1_P of the first termination region TR1. The portion TR1_P of the first termination region TR1 may include a portion of one or more first doping rings 120 and a portion of the first outer doping ring 111. For example, the first common termination region CTR1 may include a portion of one or more first doping rings 120. The one or more first doping rings 120 surround the first active region AR1, and a portion of the one or more first doping rings 120 may be disposed in the first common termination region CTR1 of the common termination region CTR.

The one or more first doping rings 120 in the first common termination region CTR1 may include a first sub-ring 121 and a second sub-ring 122 that are spaced apart from each other. A third portion P3 of the JTE region JTE may be disposed between the first sub-ring 121 and the second sub-ring 122 in the first common termination region CTR1. The first sub-ring 121 and the second sub-ring 122 in the first common termination region CTR1 may be connected to each other by the third portion P3 of the JTE region JTE.

A fourth portion P4 of the JTE region JTE may be disposed between one or more first doping rings 120 (for example, second sub-ring 122) and the first well 101 in the first common termination region CTR1.

The second common termination region CTR2 may include a portion TR2_P of the second termination region TR2. A portion TR2_P of the second termination region TR2 may include a portion of the one or more second doping rings 130 and a portion of the second outer doping ring 112. For example, the second common termination region CTR2 may include a portion of the one or more second doping rings 130. The one or more second doping rings 130 surround the second active region AR2, and a portion of the one or more second doping rings 130 may be disposed in the second common termination region CTR2 of the common termination region CTR.

The one or more second doping rings 130 in the second common termination region CTR2 may include a third sub-ring 131 and a fourth sub-ring 132 that are spaced apart from each other. A sixth portion P6 of the JTE region JTE may be disposed between the third sub-ring 131 and the fourth sub-ring 132 in the second common termination region CTR2. The third sub-ring 131 and the fourth sub-ring 132 in the second common termination region CTR2 may be connected to each other by the sixth portion P6 of the JTE region JTE.

A seventh portion of the JTE region JTE (P7) may be disposed between one or more second doping rings 130 (for example, fourth sub-ring 132) and the second well 102 in the second common termination region CTR2.

The third common termination region CTR3 may include a portion TR1_P of the first termination region TR1 and a portion TR2_P of the second termination region TR2. For example, the third common termination region CTR3 may include a portion of the first outer doping ring 111 and a portion of the second outer doping ring 112. The first outer doping ring 111 surrounds the first active region AR1, and a portion of the first outer doping ring 111 may be disposed in the third common termination region CTR3 of the common termination region CTR. The second outer doping ring 112 surrounds the second active region AR2, and a portion of the second outer doping ring 112 may be disposed in the third common termination region CTR3 of the common termination region CTR.

In the third common termination region CTR3, the first outer doping ring 111 and the second outer doping ring 112 may be disposed to be spaced apart from each other. The first portion P1 of the JTE region JTE may be disposed between the first outer doping ring 111 and the second outer doping ring 112 in the third common termination region CTR3. Since the first portion P1 of the JTE region JTE is disposed between the first outer doping ring 111 and the second outer doping ring 112 in the third common termination region CTR3, the first outer doping ring 111 and the second outer doping ring 112 can be connected to each other by the first portion P1 of the JTE region JTE. That is, a portion TR1_P of the first termination region TR1 and a portion TR2_P of the second termination region TR2 in the third common termination region CTR3 can be connected to each other by the first portion P1 of the JTE region JTE in the common termination region CTR.

A second portion P2 of the JTE region JTE may be disposed between the first outer doping ring 111 and one or more first doping rings 120 (for example, first sub-ring 121). A fifth portion P5 of the JTE region JTE may be disposed between the second outer doping ring 112 and one or more second doping rings 130 (for example, third sub-ring 131).

In FIGS. 4 and 5, the first sub-ring 121, the second sub-ring 122, the third sub-ring 131, the fourth sub-ring 132, the first outer doping ring 111, and the second outer doping ring 112 are illustrated as having the same width, but the present invention is not limited thereto. Of course, the first sub-ring 121, the second sub-ring 122, the third sub-ring 131, the fourth sub-ring 132, the first outer doping ring 111, and the second outer doping ring 112 may have different widths. Additionally, in FIGS. 4 and 5, the one or more first doping rings 120 and the one or more second doping rings 130 each are illustrated as including two sub-rings, but the present invention is not limited thereto. Of course, the one or more first doping rings 120 and the one or more second doping rings 130 each may include various numbers of sub-rings. In addition, of course, the one or more first doping rings 120 and the one or more second doping rings 130 each may include different numbers of sub-rings.

Hereinafter, a semiconductor device according to some embodiments of the present invention will be described with reference to FIGS. 1, 2, 6, and 7. For clarity of explanation, the description of those overlapping with those explained previously will be simplified or omitted.

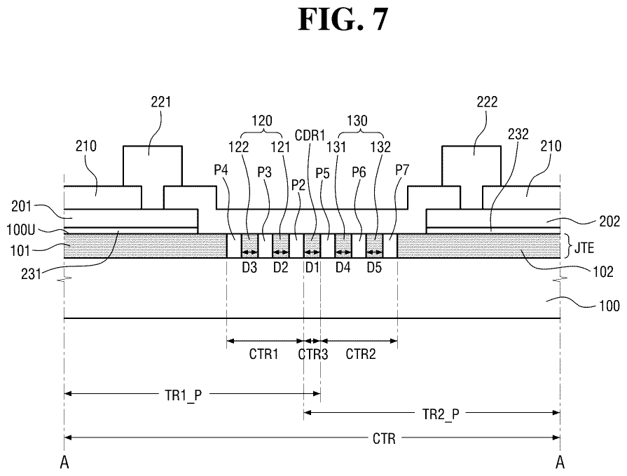

FIG. 6 is an enlarged view of region N in FIG. 1. FIG. 7 is a cross-sectional view taken along line A-A in FIGS. 2 and 4.

Referring to FIGS. 1, 2, 6, and 7, a semiconductor device according to some embodiments of the present invention may include a first common doping region CDR1 in the third common termination region CTR3.

The first common doping region CDR1 of the third common termination region CTR3 may be connected to the first outer doping ring 111 and the second outer doping ring 112. When the first outer doping ring 111 and the second outer doping ring 112 are connected to the first common doping region CDR1 in the common termination region CTR (for example, the third common termination region CTR3), a portion TR1_P of the first termination region TR1 and a portion TR2_P of the second termination region TR2 may be connected to each other. For example, the first outer doping ring 111 and the second outer doping ring 112 each may be connected by direct contact with the first common doping region CDR1 in the common termination region CTR (for example, the third common termination region CTR3).

The width of the first common doping region CDR1 may be equal to the width of the first outer doping ring 111 and the width of the second outer doping ring 112. The width of the first common doping region CDR1 may be equal to the larger of the width of the first outer doping ring 111 and the width of the second outer doping ring 112. The width of the first common doping region CDR1 may be smaller than the sum of the widths of the first outer doping ring 111 and the second outer doping ring 112, and may be larger than the smaller of the width of the first outer doping ring 111 and the width of the second outer doping ring 112.

The doping concentration of the first common doping region CDR1 may be the same as that of the first outer doping ring 111 and the second outer doping ring 112.

Hereinafter, a semiconductor device according to some embodiments of the present invention will be described with reference to FIGS. 1, 2, 8, and 9. For clarity of explanation, the description of those overlapping with those explained previously will be simplified or omitted.

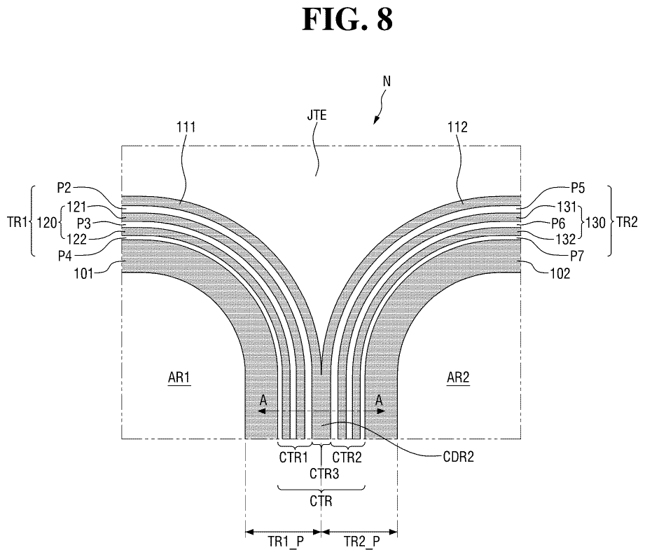

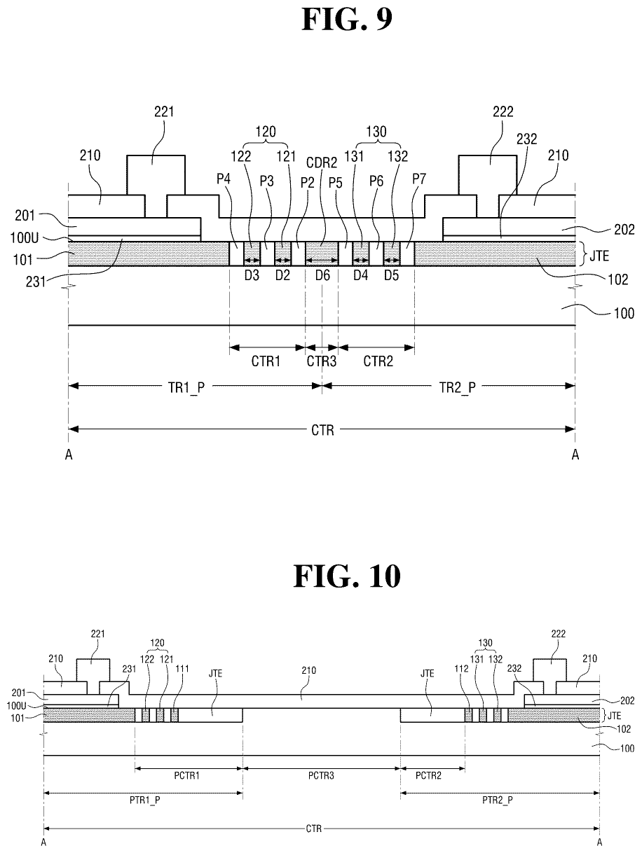

FIG. 8 is an enlarged view of region N in FIG. 1. FIG. 9 is a cross-sectional view taken along line A-A in FIGS. 2 and 4.

Referring to FIGS. 1, 2, 8, and 9, a semiconductor device according to some embodiments of the present invention may include a second common doping region CDR2 in the third common termination region CTR3.

The second common doping region CDR2 of the third common termination region CTR3 may be connected to the first outer doping ring 111 and the second outer doping ring 112. When the first outer doping ring 111 and the second outer doping ring 112 are connected to the second common doping region CDR2 in the common termination region CTR (for example, the third common termination region CTR3), a portion TR1_P of the first termination region TR1 and a portion TR2_P of the second termination region TR2 can be connected to each other. For example, the first outer doping ring 111 and the second outer doping ring 112 each may be in direct contact with the second common doping region CDR2 in the common termination region CTR (for example, the third common termination region CTR3).

The width of the second common doping region CDR2 may be larger than the width of the first outer doping ring 111 and the width of the second outer doping ring 112. The width of the second common doping region CDR2 may be equal to or larger than the sum of the widths of the first outer doping ring 111 and the second outer doping ring 112.

The doping concentration of the second common doping region CDR2 may be the same as that of the first outer doping ring 111 and the second outer doping ring 112.

FIG. 10 is a cross-sectional view of a conventional semiconductor device. For clarity of explanation, the description of those overlapping with those explained previously will be omitted.

Referring to FIG. 10, unlike the semiconductor device according to the embodiment of the present invention, the JTE region JTE in the conventional semiconductor device may not be connected in the conventional third common termination region CTR3. The common termination region CTR includes a portion TR1_P of the first termination region TR1 and a portion TR2_P of the second termination region TR2, but these portions may not be connected to each other. A portion of the substrate 100 may be disposed between a portion TR1_P of the first termination region TR1 and a portion TR2_P of the second termination region TR2.

In the semiconductor device according to the embodiment of the present invention, a first transistor including a first active region and a second transistor including a second active region each have a termination region (for example, a first termination region and a second termination region), and a common termination region is disposed between the first active region and the second active region. Therefore, the design rule can be shortened to reduce the chip size, the conduction distance between the first transistor and the second transistor can be reduced to reduce conduction loss, and low resistance can be secured.

In the semiconductor device according to the embodiment of the present invention, the first termination region and the second termination region are connected through a portion of the JTE region in the common termination region, or the first termination region and the second termination region are connected through a common doping region. Therefore, the design rule can be shortened and the chip size can be further reduced.

While the inventive concept has been particularly shown and described with reference to exemplary embodiments thereof, it will be understood by those of ordinary skill in the art that various changes in form and details may be made therein without departing from the spirit and scope of the inventive concept as defined by the following claims. It is therefore desired that the embodiments be considered in all respects as illustrative and not restrictive, reference being made to the appended claims rather than the foregoing description to indicate the scope of the disclosure.

What is claimed is:

1. A semiconductor device comprising:
a substrate;
a first active region on the substrate;
a second active region on the substrate separated from the first active region;
a common termination region between the first active region and the second active region;
a junction termination extension (JTE) region surrounding the first active region and the second active region;
a first termination region between the JTE region and the first active region, surrounding the first active region; and
a second termination region between the JTE region and the second active region, surrounding the second active region, wherein
a portion of the first termination region and a portion of the second termination region are connected to each other at the common termination region.

2. The semiconductor device according to claim 1, wherein
the first termination region includes one or more first doping rings and a first outer doping ring surrounding the one or more first doping rings, and
the second termination region includes one or more second doping rings and a second outer doping ring surrounding the one or more second doping rings.

3. The semiconductor device according to claim 2, further comprising:
a first portion of the JTE region disposed between the first outer doping ring and the second outer doping ring in the common termination region, wherein
a portion of the first termination region and a portion of the second termination region are connected to each other by the first outer doping ring, the second outer doping ring, and the first portion of the JTE region in the common termination region.

4. The semiconductor device according to claim 3, wherein
the one or more first doping rings include a first sub-ring and a second sub-ring that are spaced apart from each other,
a second portion of the JTE region is disposed between the first sub-ring and the second sub-ring, and
the one or more first doping rings and the first outer doping ring are connected to each other by a third portion of the JTE region.

5. The semiconductor device according to claim 2, further comprising:
a common doping region, to which the first outer doping ring and the second outer doping ring are connected, in the common termination region, wherein
a portion of the first termination region and a portion of the second termination region are connected to each other by the common doping region in the common termination region.

6. The semiconductor device according to claim 5, wherein
the one or more first doping rings include a first sub-ring and a second sub-ring that are spaced apart from each other,
a second portion of the JTE region is disposed between the first sub-ring and the second sub-ring, and
the one or more first doping rings and the common doping region are connected to each other by a third portion of the JTE region.

7. The semiconductor device according to claim 5, wherein a width of the common doping region is equal to widths of the one or more first doping rings.

8. The semiconductor device according to claim 5, wherein
a width of the common doping region is greater than widths of the one or more first doping rings.

9. A semiconductor device comprising:
a substrate;
a first active region on the substrate;
a second active region on the substrate separated from the first active region;
a common termination region between the first active region and the second active region;
a junction termination extension (JTE) region disposed within the substrate, being a partial region of the substrate including an upper surface of the substrate in the common termination region;
a first well and a second well disposed within the JTE region of the common termination region and spaced apart from each other;
a first outer doping ring surrounding the first active region and disposed between the first well and the second well within the JTE region of the common termination region;
one or more first doping rings surrounding the first active region and disposed between the first well and the first outer doping ring within the JTE region of the common termination region; and
one or more second doping rings surrounding the second active region and disposed between the second well and the first outer doping ring within the JTE region of the common termination region.

10. The semiconductor device according to claim 9, further comprising:
a second outer doping ring surrounding the second active region and disposed between the first outer doping ring and the one or more second doping rings within the JTE region of the common termination region, wherein
the first outer doping ring and the second outer doping ring are connected to each other by a first portion of the JTE region.

11. The semiconductor device according to claim 10, wherein
the one or more first doping rings include a first sub-ring and a second sub-ring that are spaced apart from each other,
a second portion of the JTE region is disposed between the first sub-ring and the second sub-ring, and
the one or more first doping rings and the first outer doping ring are connected to each other by a third portion of the JTE region.

12. The semiconductor device according to claim 9, further comprising:
a second outer doping ring surrounding the second active region and the one or more second doping rings; and
a common doping region, to which the first outer doping ring and the second outer doping ring are connected, within the JTE region of the common termination region.

13. The semiconductor device according to claim 12, wherein
the one or more first doping rings include a first sub-ring and a second sub-ring that are spaced apart from each other,
a second portion of the JTE region is disposed between the first sub-ring and the second sub-ring, and
the one or more first doping rings and the common doping region are connected to each other by a third portion of the JTE region.

14. The semiconductor device according to claim 12, wherein
a width of the common doping region is equal to widths of the one or more first doping rings.

15. The semiconductor device according to claim 12, wherein
a width of the common doping region is greater than widths of the one or more first doping rings.

16. A semiconductor device comprising:
a substrate;
a first active region on the substrate;
a second active region on the substrate separated from the first active region;
a common termination region between the first active region and the second active region;
a junction termination extension (JTE) region disposed within the substrate, being a partial region of the substrate including an upper surface of the substrate in the common termination region;
a first well and a second well disposed within the JTE region of the common termination region and spaced apart from each other;
a common doping region disposed between the first well and the second well within the JTE region of the common termination region;
one or more first doping rings surrounding the first active region and disposed between the first well and the common doping region within the JTE region of the common termination region; and
one or more second doping rings surrounding the second active region and disposed between the second well and the common doping region within the JTE region of the common termination region.

17. The semiconductor device according to claim 16, wherein
the common doping region and the one or more first doping regions are connected to each other by a first portion of the JTE region, and
the common doping region and the one or more second doping regions are connected to each other by a second portion of the JTE region.

18. The semiconductor device according to claim 17, wherein
the one or more first doping rings include a first sub-ring and a second sub-ring,
the first sub-ring and the second sub-ring are connected to each other by a third portion of the JTE region,
the one or more second doping rings include a third sub-ring and a fourth sub-ring, and
the third sub-ring and the fourth sub-ring are connected to each other by a second portion of the JTE region.

19. The semiconductor device according to claim 16, wherein
the one or more first doping rings include a first sub-ring,
the one or more second doping rings include a second sub-ring, and
a width of the common doping region, a width of the first sub-ring, and a width of the second sub-ring are the same.

20. The semiconductor device according to claim 16, wherein
the one or more first doping rings include a first sub-ring,
the one or more second doping rings include a second sub-ring, and
a width of the common doping region is wider than a width of the first sub-ring and a width of the second sub-ring.
